(19) United States
(12) Patent Application Publication
(10) Pub. No.: US 2025/0253268 A1
(43) Pub. Date: Aug. 7, 2025

(54) PROTECTION DEVICE FOR METAL INSULATOR METAL (MIM) CAPACITOR

(71) Applicant: Intel Corporation, Santa Clara, CA (US)

(72) Inventors: James WALDEMER, Hillsboro, OR (US); Rahim KASIM, Portland, OR (US); Christopher PERINI, Hillsboro, OR (US); James PALMER, Portland, OR (US); Mark ARMSTRONG, Portland, OR (US); Yang YANG, Portland, OR (US); Yunzhe Thomas MA, Portland, OR (US)

(21) Appl. No.: 18/435,510

(22) Filed: Feb. 7, 2024

(51) Int. Cl. H01L 23/60; H01L 23/14; H01L 23/498; H01L 23/64; H01L 23/66; H01L 29/872

(52) U.S. Cl. CPC H01L 23/60; H01L 23/14; H01L 23/49822; H01L 23/49844; H01L 23/49866; H01L 23/642; H01L 23/66; H10D 1/042; H10D 1/716; H10D 8/60; H01L 2223/6616; H01L 2223/6672; H01L 2223/6677

(57) ABSTRACT

A protection device for metal insulator metal (MIM) capacitors are described. In an example, an electronic assembly includes a semiconductor substrate. A dielectric layer is on the semiconductor substrate. A conductive via is in an opening in the dielectric layer, the conductive via in direct contact with the semiconductor substrate. A metal-insulator-metal (MIM) capacitor structure is electrically coupled to the conductive via.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. The drive for ever-more capacity, however, is not without issue. The necessity to optimize the performance of each device becomes increasingly significant.

Variability in conventional and currently known fabrication processes may limit the possibility to further extend them into smaller and smaller nodes. Consequently, fabrication of the functional components needed for future technology nodes may require the introduction of new methodologies or the integration of new technologies in current fabrication processes or in place of current fabrication processes.

An interposer is an electrical interface routing between a die and a package substrate or a board. The purpose of an interposer can be to spread a connection to a wider pitch or to reroute a connection to a different connection.

### BRIEF DESCRIPTION OF THE DRAWINGS

FIG. 1A illustrates a cross-sectional view of a portion of an electronic assembly, which shows the Cu via landing directly onto the Si substrate forming a Schottky diode, in accordance with an embodiment of the present disclosure.

FIG. 1B illustrates a cross-sectional view of a portion of an electronic assembly, in accordance with an embodiment of the present disclosure.

FIG. 1C is a schematic of a band diagram of a Cu/Si interface between a copper metal structure and a silicon structure, in accordance with an embodiment of the present disclosure.

FIG. 1D is a schematic illustrating process induced damage that can occur due to charge buildup across two MIM electrodes, in accordance with an embodiment of the present disclosure.

FIG. 1E includes a schematics representing protection schemes, in accordance with an embodiment of the present disclosure.

FIG. 1F is a schematic illustrating charge equilibration through a back-to-back diode scheme, where charge bleeds across the first diode, through the silicon substrate, and into the opposite electrode's net, in accordance with an embodiment of the present disclosure.

FIGS. 2 and 3 show probability plots of the measured 2V leakage for three different wafers (samples 1-3) of two different structures, in accordance with an embodiment of the present disclosure.

FIG. 4A is a cross-sectional illustration of an interposer with a capacitor region, in accordance with an embodiment of the present disclosure.

FIG. 4B is a cross-sectional illustration of a deep trench capacitor architecture, in accordance with an embodiment of the present disclosure.

FIG. 5 illustrates a basic schematic depicting the integration of a MIM decoupling capacitor into an interconnect stack, in accordance with an embodiment of the present disclosure.

FIG. 6 illustrates an angled cross-sectional view of an integrated capacitor structure, in accordance with an embodiment of the present disclosure.

FIG. 7 illustrates an angled cross-sectional view of an integrated capacitor structure, in accordance with an embodiment of the present disclosure.

FIG. 8 illustrates a computing device in accordance with one implementation of the disclosure.

FIG. 9 illustrates an interposer that includes one or more embodiments of the disclosure.

### DESCRIPTION OF THE EMBODIMENTS

Protection devices for metal insulator metal (MIM) capacitors are described. In the following description, numerous specific details are set forth, such as specific integration and material regimes, in order to provide a thorough understanding of embodiments of the present disclosure. It will be apparent to one skilled in the art that embodiments of the present disclosure may be practiced without these specific details. In other instances, well-known features are not described in detail in order to not unnecessarily obscure embodiments of the present disclosure. Furthermore, it is to be appreciated that the various embodiments shown in the Figures are illustrative representations and are not necessarily drawn to scale.

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions or context for terms found in this disclosure (including the appended claims):

“Comprising.” This term is open-ended. As used in the appended claims, this term does not foreclose additional structure or operations.

“Configured To.” Various units or components may be described or claimed as “configured to” perform a task or tasks. In such contexts, “configured to” is used to connote structure by indicating that the units or components include structure that performs those task or tasks during operation. As such, the unit or component can be said to be configured to perform the task even when the specified unit or component is not currently operational (e.g., is not on or active). Reciting that a unit or circuit or component is “configured to” perform one or more tasks is expressly intended not to invoke 35 U.S.C. § 112, sixth paragraph, for that unit or component.

“First,” “Second,” etc. As used herein, these terms are used as labels for nouns that they precede, and do not imply any type of ordering (e.g., spatial, temporal, logical, etc.).

“Coupled”—The following description refers to elements or nodes or features being “coupled” together. As used herein, unless expressly stated otherwise, “coupled” means that one element or node or feature is directly or indirectly joined to (or directly or indirectly communicates with) another element or node or feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation or location or both of portions of the component within a consistent but arbitrary frame of reference which is made clear by reference to the text and the associated drawings describing the component under discussion. Such terminology may include the words specifically mentioned above, derivatives thereof, and words of similar import.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, or effect which might otherwise occur. Accordingly, when a component, element, or feature is referred to as inhibiting a result or state, it need not completely prevent or eliminate the result or state.

Embodiments described herein may be directed to back-end-of-line (BEOL) semiconductor processing and structures. BEOL is a portion of IC fabrication where interconnects or wirings or routing layers are formed on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed.

Embodiments described below may be applicable to front-end-of-line (FEOL) processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

One or more embodiments are directed to copper via to silicon substrate back-to-back Schottky diode configurations as a passive interposer process induced damage (PID) protection device. In accordance with one or more embodiments of the present disclosure, a protection device for a metal insulator metal (MIM) capacitor is described. In an embodiment, unlike active interposers, passive interposers only contain metal interconnects and do not include active logic like routers, re-peaters, or FIFO queues in the interposer.

To provide context, process induced damage (PID) rules exist to protect victims against in-process charging effects that can degrade or induce failure to the victims. These victims traditionally are the gate oxide high-k layer and the metal insulator metal (MIM) high-k layer, both of which are thin dielectric layers which can be susceptible to charge buildup during wafer-processing that can cause damage or failure. Traditionally, these victims are protected by design rules which require a PID protection device to be connected to the victim. This protection device ensures that any charge buildup that occurs on the victim's net can be dissipated away from the victim through the protection device, as opposed to through the victim itself. These protection devices have historically been transistor based (e.g. GNACs), where the device is a transistor that self-regulates based on source-to-drain leakage.

With the introduction of a MIM structure to a passive interposer, a scenario can arise where a wafer stack or substrate has a MIM victim but no front-end transistors. This means the conventional strategy of transistor protection devices cannot be leveraged. As such, a process architecture was that provides PID protection to the MIM without the use of FEOL transistor protection devices is described herein.

Prior technologies with MIM structures were able to leverage the FE transistor PID protection devices on the chip. Passive interposers pose a unique case where no FE transistor devices can be used or are available for PID protection.

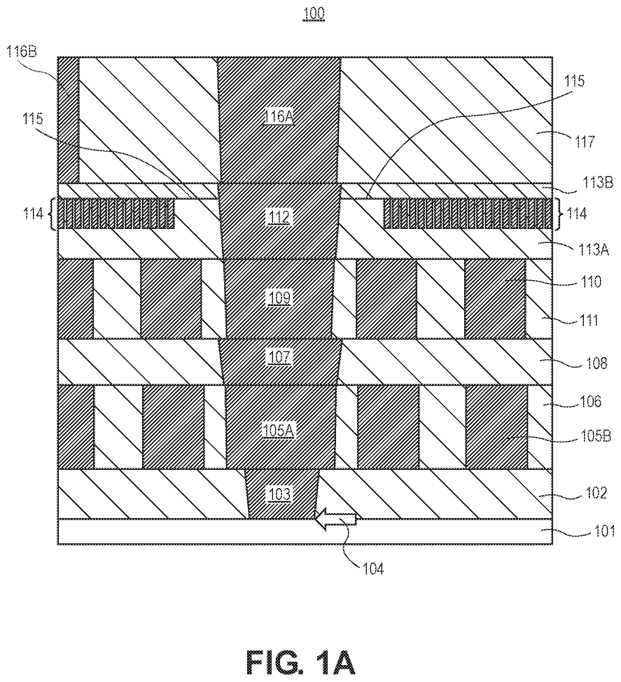

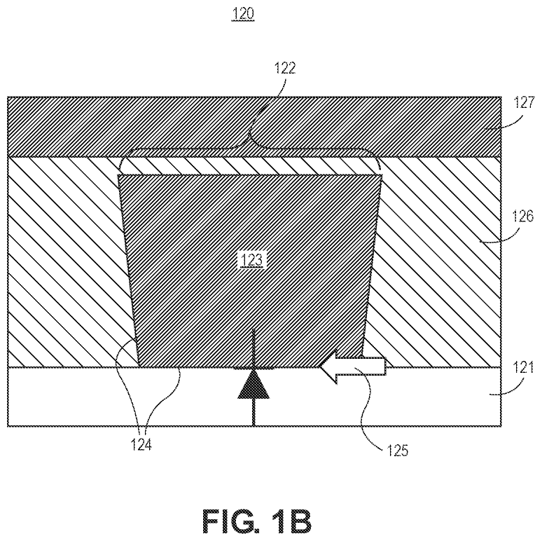

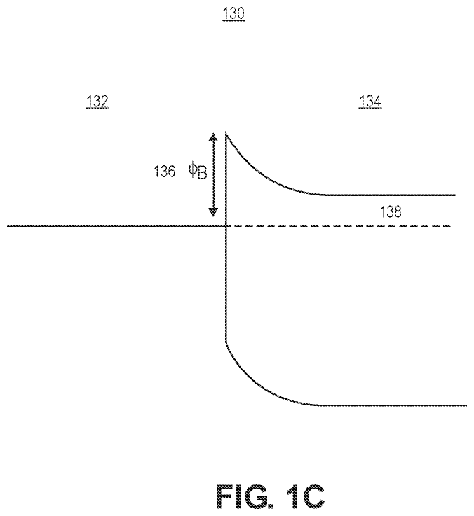

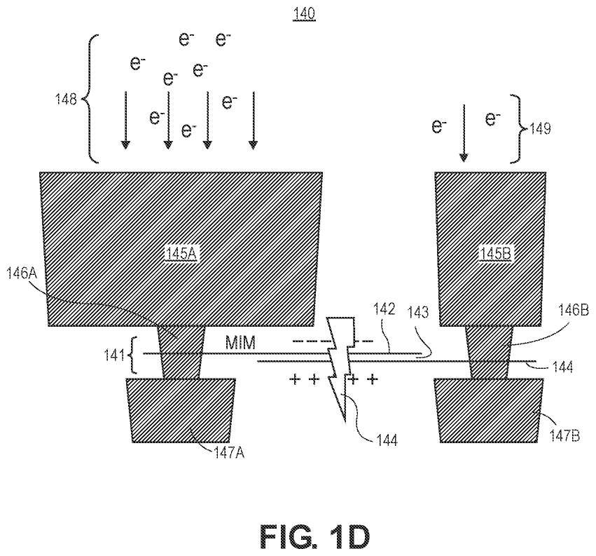

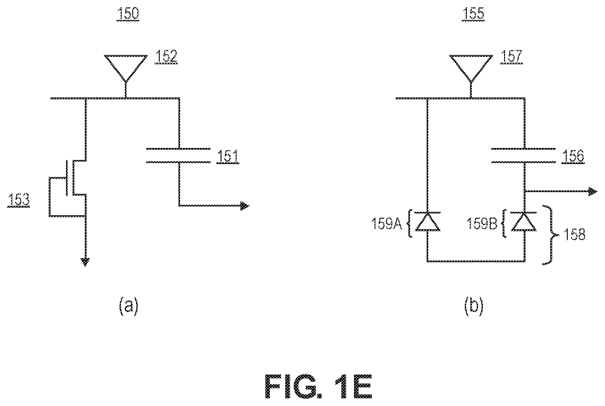

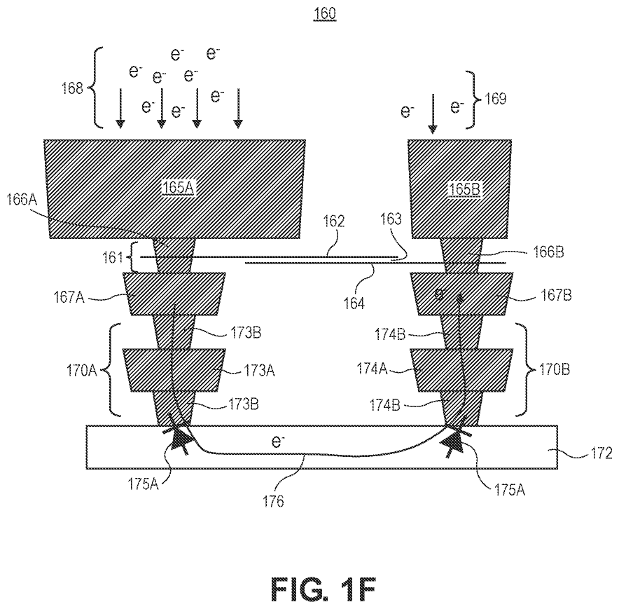

In accordance with an embodiment of the present disclosure, a PID protection device architecture is fabricated by landing copper vias directly onto the silicon substrate (e.g., see FIGS. 1A and 1B, described below). The Cu/Si interface forms a Schottky diode, which when paired in sets of two (one diode per MIM net) creates a back-to-back Schottky diode scheme. In an embodiment, this scheme allows charge to bleed from one net across the reverse polarity diode and flow freely through the corresponding forward polarity diode, equilibrating charge between the two MIM nets without having leakage drop across the MIM high-k layer.

In accordance with an embodiment of the present disclosure, a back-to-back diode scheme enables PID protection in the absence of a front-end process, allowing a MIM structure to be protected in passive interposers. Without a diode scheme as disclosed herein, the MIM structure would otherwise may be unprotected to PID issues and at risk for degradation or damage during wafer processing. Such degradation or damage can manifest as either time0 defects (yield) or latent damage that would manifest as a part failure in customer hands (reliability).

The implementation of embodiments disclosed herein may be detectable by reverse engineering the diode scheme by performing cross-SEM or cross-TEM imaging of the stack, which may reveal Cu vias landing directly on a Si substrate. For example, such analysis could reveal Cu vias landing directly on the Si substrate.

In an embodiment, a diode scheme results in Cu diodes landing directly on the Si substrate, as is described in association with below in FIG. 1A and FIG. 1B. In one embodiment, the diode that is formed is due to the Schottky energy barrier between the work function of the Cu metal and the conduction band minimum of the Si semiconductor, as described in association with FIG. 1C.

FIG. 1A illustrates a cross-sectional view of a portion of an electronic assembly, such as a backend stack with a Cu via landing directly onto the Si substrate to form a Schottky diode, in accordance with an embodiment of the present disclosure. The diode is connected to one or more nets that connect to MIM (which in this case is topographic).

Referring to FIG. 1A, an electronic assembly 100, such as a passive interposer, includes a semiconductor substrate 101, such as a silicon substrate. A dielectric layer 102 is on the semiconductor substrate 101. A conductive via 103, such as a copper via, is in an opening in the dielectric layer 102 and is in direct electrical contact with the semiconductor substrate 101. In one embodiment, the conductive via 103 and the semiconductor substrate 101 form a Schottky diode 104.

Referring again to FIG. 1A, one or more routing layers can be included above the conductive via 103. In a particular embodiment, the routing layers include a layer including conductive lines 105A and 105B in a dielectric layer 106, a layer including a conductive via 107 in a dielectric layer 108, a layer including conductive lines 109 and 110 in a dielectric layer 111. It is to be appreciated that the number of routing layers can vary depending on the application.

Referring again to FIG. 1A, a capacitor layer includes MIM capacitor structures 114 and a conductive via 112 in a dielectric layer 113A, which can include a passivation layer 113B thereon. An additional routing layer, e.g., including conductive lines 116A and 116B in a dielectric layer 117 can be formed above the capacitor layer, as is depicted. In one embodiment, the MIM capacitor structures 114 are topographical or trench MIM capacitors, as is depicted. In another embodiment, the MIM capacitor structures 114 are stacked plate MIM capacitors. In another embodiment, the MIM capacitor structures 114 are finger MIM capacitors.

Referring again to FIG. 1A, the MIM capacitor structures 114 are coupled to the conductive via 112 by a conductive line or plate extension (referred to generally as a net 115 of the capacitor structure). The net 115 is electrically coupled to the conductive via 103, e.g., by conductive line 109, conductive via 107, and conductive line 105A, as is depicted.

FIG. 1B illustrates a cross-sectional view of a portion of an electronic assembly, in accordance with an embodiment of the present disclosure. The electronic assembly 120 includes a conductive via 122, which may be similar to conductive via 103 and vice versa. The conductive via forms a Schottky diode 125 with a semiconductor substrate 121. The conductive via 122 is in a dielectric layer 126 and can be beneath an overlying conductive line 127. In an embodiment, the conductive via 122 includes a conductive liner 124 and a conductive fill 123. In one embodiment, the conductive 124 liner includes a layer of tantalum, e.g., having a thickness in the range of 1-25 nanometers. In one embodiment, the conductive fill 123 includes copper. In other embodiments, the conductive fill includes cobalt or tungsten. In an embodiment, the conductive liner 124 is in direct physical contact with the semiconductor substrate 121, and the conductive fill 123 is in direct physical contact with the conductive 124 liner. In an embodiment, as used throughout, although a conductive line may be included between a copper fill of a conductive via and a silicon substrate, since the copper fill is directly electrically connected to the silicon substrate, the arrangement is referred to as having a copper/silicon interface or as having copper directly on the silicon.

FIG. 1C is a schematic of a band diagram 130 of a Cu/Si interface between a copper metal structure 132 and a silicon structure 134, in accordance with an embodiment of the present disclosure. The band diagram 130 includes a Schottky barrier height 136 and a Fermi energy 138. Band diagram 130 depicts the Schottky barrier height 136 that is leveraged to form a diode between the metal and semiconductor.

To provide further context, during wafer processing, particularly in highly energetic process steps (e.g., via or trench etches), a MIM structure can experience process induced damage effects due to a potential imbalance across the MIM high-k dielectric. In extreme cases, the two electrodes of a MIM may be connected to largely asymmetric metal antenna areas, which in turn can getter charge asymmetrically. This asymmetric charge buildup can result in a large delta voltage across the MIM high-k, which can result in damage or degradation that can manifest as both time0 fails (i.e., yield) as well as customer-facing fails (i.e. reliability). A schematic of this antenna/victim relationship is shown in FIG. 1D.

FIG. 1D is a schematic illustrating process induced damage that can occur due to charge buildup across two MIM electrodes, in accordance with an embodiment of the present disclosure.

Referring to FIG. 1D, an electronic assembly 140 includes a MIM structure 141. The MIM structure 141 includes an electrode layer 142, a high-k dielectric layer 143, and an electrode layer 144. An antenna 145A is coupled to the electrode layer 142, e.g., by a via 146A which can in turn be coupled to a conductive line 147A. An antenna 145B is coupled to the electrode layer 144, e.g., by a via 146B which can in turn be coupled to a conductive line 147B. Because the metal antenna areas connected to the two sides of the MIM are asymmetric, charge builds up non-uniformly on both sides of the MIM, e.g., shown as 148 versus 149, resulting in a voltage delta across the MIM high-k layer.

To provide further context, traditional PID protection schemes involve transistor devices, commonly in a GCAC configuration, to dissipate charge off an antenna that is connected to a victim. A schematic of how a GNAC could be connected to protect a MIM victim is shown in part (a) of FIG. 1E, where the GNAC can bleed off charge built up on the antenna, dissipating it away from the MIM victim. The dissipation through the protection device ensures that the victim does not experience charge buildup, protecting the victim from any degradation or damage. These traditional schemes require front-end (FE) processing to create these transistors, which can mean that the scheme cannot be used for passive interposers that only have upper-back-end metal layers in the stack.

In accordance with an embodiment of the present disclosure, to ensure that the MIM victims have requisite PID protection in a passive interposer, the Schottky diode scheme can be implemented allow charge to bleed from the antenna net connected to one MIM electrode through the back-to-back diodes into the opposite MIM electrode's net. This can ensure that there is an equipotential between the two MIM electrodes, mitigating any delta voltage across the high-k layer that can result in creating latent or time0 defects. This scheme is depicted in part (b) of FIG. 1E.

FIG. 1E includes a schematics representing protection schemes 150 and 155, in accordance with an embodiment of the present disclosure. Referring to part (a) of FIG. 1E, a traditional GNAC 153 can be used to protect a MIM victim 151 from an antenna 152. Referring to part (b) of FIG. 1E, a Schottky back-to-back (BTB) diode 158 (e.g., including diodes 159A and 159B) can be used to protect a MIM victim 156 from an antenna 157.

In an embodiment, with the BTB diodes in place, the asymmetric charge built up in the example shown in FIG. 1D is provided with an avenue to equilibrate across the MIM without conduction through the MIM high-k layer. The significant charge buildup on one MIM electrode's net can bleed across the reverse bias diode into the substrate, and can then flow freely through the second forward bias diode into the opposite MIM electrode net. This equilibration behavior is depicted in FIG. 1F. The scheme mitigates the high-k layer from experiencing significant delta voltage during wafer manufacturing.

FIG. 1F is a schematic illustrating charge equilibration through a back-to-back diode scheme, where charge bleeds across the first diode, through the silicon substrate, and into the opposite electrode's net, in accordance with an embodiment of the present disclosure.

Referring to FIG. 1F, an electronic assembly 160 includes a MIM structure 161. The MIM structure 161 includes an electrode layer 162, a high-k dielectric layer 163, and an electrode layer 164. An antenna 165A is coupled to the electrode layer 162, e.g., by a via 166A which can in turn be coupled to a conductive line 167A and to additional routing layers 170A such as conductive lines 173A and vias 173B. An antenna 165B is coupled to the electrode layer 164, e.g., by a via 166B which can in turn be coupled to a conductive line 167B and to additional routing layers 170B such as conductive lines 174A and vias 174B. In an embodiment, the bottommost vias 173B and 174B are in direct contact with a semiconductor substrate 172, such as a silicon substrate, e.g., to form diodes 175A (which can be coupled by pathway 176 in semiconductor substrate 172. In an embodiment, even though the metal antenna areas connected to the two sides of the MIM are asymmetric, non-uniform charge 168 versus 169 can be equilibrated.

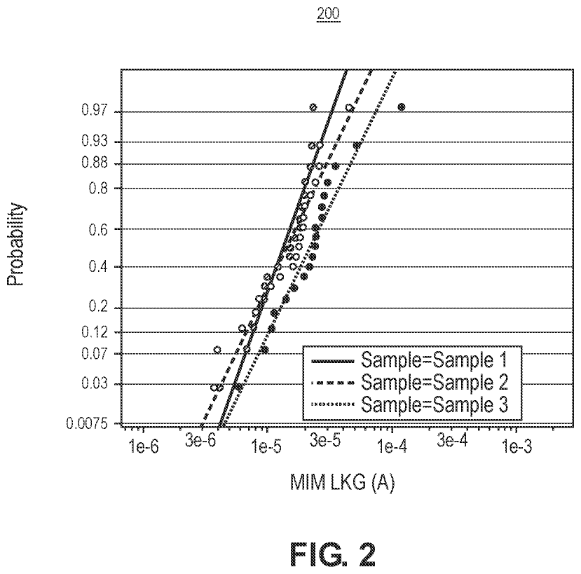

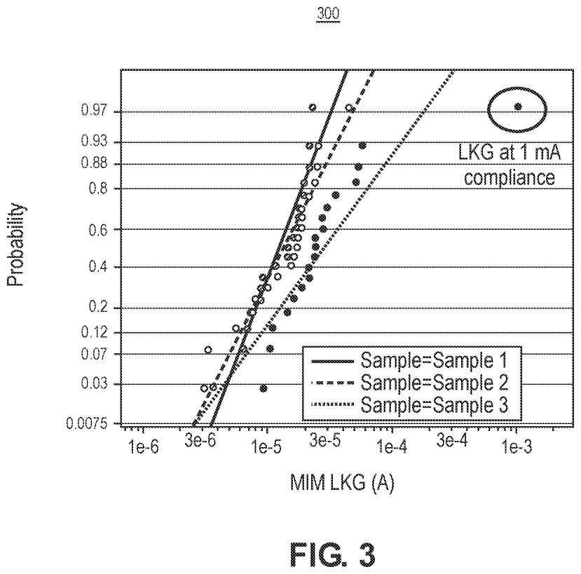

In an embodiment, one indicator of whether the MIM experiencing PID damage is monitoring the time0 leakage of the MIM. If there are leakage high-fliers, that can indicate that there are PID-induced defects and damage that degrade or break the MIM before it even reaches the end of the manufacturing line. FIGS. 2 and 3 show probability plots of the measured 2V leakage for three different wafers (samples 1-3) of two different structures, in accordance with an embodiment of the present disclosure. Plot 200 of FIG. 2 shows leakage from a MIM structure that has requisite diode protection. This structure shows a healthy distribution of leakages without any high-fliers, indicating the MIM is well-behaved and did not experience any PID effects. By contrast, the plot 300 of FIG. 3 shows leakage from a MIM structure without protection diodes. This structure shows one site of with significantly elevated leakage, reaching the 1 mA compliance limit of the measurement. This high-flier is indicative of a PID tail effect that manifests in the unprotected MIM structure. These results indicate that unprotected MIM can experience PID effects that can result in a time0 failure, but these effects can be mitigated with the use of the novel back-to-back Schottky diode PID protection scheme.

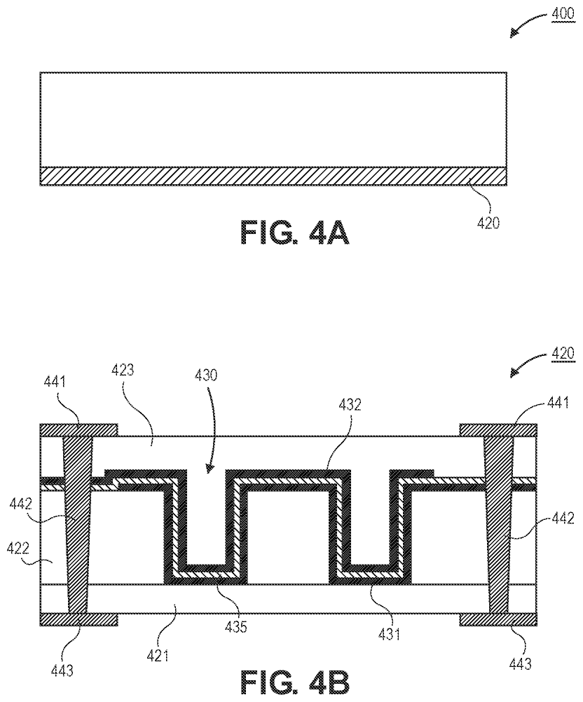

FIG. 4A is a cross-sectional illustration of an interposer with a capacitor region, in accordance with an embodiment of the present disclosure.

Referring now to FIG. 4A, a cross-sectional illustration of an interposer with a capacitor region is shown, in accordance with an embodiment of the present disclosure. On the backside of the interposer 400, a capacitor region 420 is provided. The capacitor region 420 may be provided in the BEOL stack of the interposer 400. Typically, the capacitors of the capacitor region 420 are provided in the last routing layers of the BEOL stack. The capacitor region 420 is shown as a generic block in FIG. 4A, however, it is to be appreciated that the capacitor architectures within the capacitor region 420 may include any capacitor structure such as those described in greater detail herein. For example, the capacitor region 420 may include deep trench capacitor architectures or stacked plate capacitor architectures or finger capacitor architectures.

As an exemplary trench capacitor, referring now to FIG. 4B, a cross-sectional illustration of a capacitor region 420 is shown, in accordance with an embodiment of the present disclosure. In an embodiment, the capacitor region 420 may be fabricated in one or more buildup layers 421, 422, and 423. The capacitor region 420 may include a plurality of deep trench capacitors. Each deep trench capacitor is provided in a trench 430 formed into the buildup layer 422. The capacitor itself may include a first electrode 431, an insulating layer 435, and a second electrode 432. The first electrode 431, the insulating layer 435, and the second electrode 432 may line the trench 430 and have U-shaped cross-sections. The individual capacitors may be coupled together by layers over a top surface of the buildup layer 422. Additionally, the second electrode 432 may be contacted by a via 442 (i.e., left via 442) that is provided between pads 441 and 443. The first electrode 431 may be contacted by a via 442 (i.e., right via 442) that is provided between pads 441 and 443.

In the illustrated embodiment, a pair of trenches 430 are shown for simplicity. However, it is to be appreciated that tens, hundreds, or thousands, of trenches 430 may be provided in the capacitor region 420. For example, the trenches 430 may occupy an area that is approximately 50 μm by 50 μm or larger in some embodiments.

As shown, the thickness of the first electrode 431, the insulating layer 435, and the second electrode 432 need to be thin in order to fit into the deep trench 430. For example, the layers 431, 435, and 432 may be formed with ALD processes or other conformal deposition process. Particularly, the width of the trench 430 may be 100 nm or smaller. As capacitor density is increased, the trench 430 width is decreased, and limits the thicknesses of layers 431, 435, and 432. Thin thicknesses of the electrodes 431 and 432 results in a higher resistance for the capacitor and decreases performance.

In an embodiment, an ALD high-k dielectric stack includes HfO₂, ZrO₂, SrTiO₃, BaTiO₃, BaHfO₃, BaZrO₃, LaALO₃, LaCoO₃, SrSnO₃ or combinations thereof. In an embodiment, ALD conductive layer/electrodes to enable high AR deposition can include (1) ALD Ru, RuO₂, IrO₂, Mo, MoO₂, Rh, Re, W, or Pt, or (2) ALD ABX₃ perovskite complex oxides, e.g. LaNiO₃, LaRuO₃, SrVO₃, SrCoO₃, SrMoO₃, or SrRuO₃ to enable high quality metal-insulator interface.

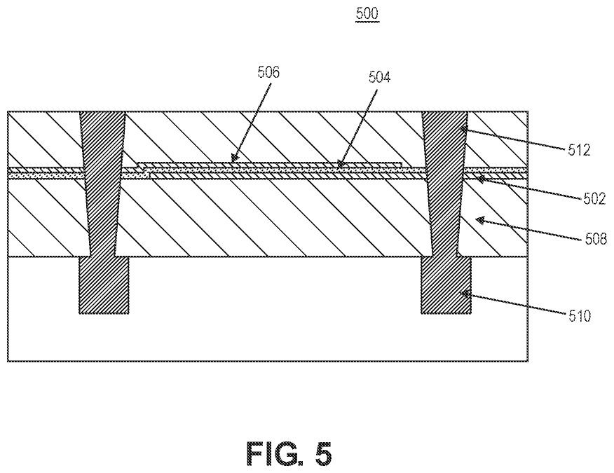

As an exemplary stacked plate capacitor, FIG. 5 illustrates a basic schematic depicting the integration of a MIM capacitor into a via interconnect stack. Referring to FIG. 5, an integrated circuit structure 500 includes a MIM capacitor having a bottom plate 502, a high-k dielectric layer 504, and a top plate 506. The MIM capacitor is integrated within a passivation material 508. Metal layers 510 are below the MIM capacitor. MIM contact vias 512 contact the MIM capacitor and the metal layers 510. In particular, the MIM contact via 512 on the right contacts the bottom plate 502, and the MIM contact via 512 on the left contacts the top plate 506. It is to be appreciated that additional plates such as a third plate or even more additional plates may be included in the MIM capacitor structure.

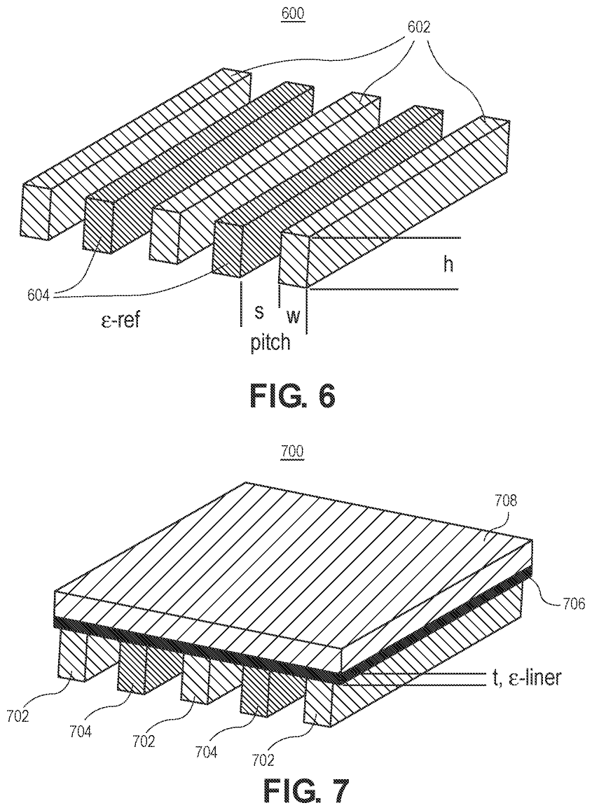

As an exemplary finger capacitor, FIG. 6 illustrates an angled cross-sectional view of an integrated capacitor structure, in accordance with an embodiment of the present disclosure.

Referring to FIG. 6, an integrated capacitor structure 600 includes alternating first metal lines 602 and second metal lines 604, which may be referred to as fingers. The first metal lines 602 are coupled together to a first polarity, e.g., at a location into or out of the page. The second metal lines 604 are coupled together to a second polarity opposite the first polarity, e.g., at a location into or out of the page. The first metal lines 602 and the second metal lines 604 are included in a dielectric layer, such as a BEOL dielectric layer, referred to generally as ε-ref. Individual ones of the first metal lines 602 and the second metal lines 604 can have a spacing(s), a width (W), a height (h), and a pitch, all of which contribute to the overall capacitance of the integrated capacitor structure 600.

In accordance with one or more embodiments of the present disclosure, the tolerance of a capacitor is improved by adding additional dielectric and metallic layers on top or below capacitor finger structures. With these layers, an additional capacitor contributor is added, which has low variation (good control of layer thickness versus lithographically defined distances) and is not correlated to the initial variation. In an embodiment, such an arrangement leads to an overall reduction of the tolerance. Advantages of implementing one or more embodiments described herein can include that the fabrication of device enhancement circuits with lower power consumption and higher frequencies for improved data rate can be designed.

In contrast to FIG. 6, FIG. 7 illustrates an angled cross-sectional view of an integrated capacitor structure, in accordance with an embodiment of the present disclosure.

Referring to FIG. 7, an integrated capacitor structure 700 includes alternating first metal lines 702 and second metal lines 704, which may be referred to as fingers. The first metal lines 702 are coupled together to a first polarity, e.g., at a location into or out of the page. The second metal lines 704 are coupled together to a second polarity opposite the first polarity, e.g., at a location into or out of the page. The first metal lines 702 and the second metal lines 704 are included in a dielectric layer, such as a BEOL dielectric layer. Individual ones of the first metal lines 702 and the second metal lines 704 can be as described in association with integrated capacitor structure 600 of FIG. 6. In an embodiment, integrated capacitor structure 700 includes at least one metal plate 708 and intervening dielectric liner layer 706 (the latter showing having a thickness, t, and a liner permittivity, ε-liner).

Referring again to FIG. 7, in one embodiment, a single metal plate 708 and intervening dielectric liner layer 706 pair are included over a “finger” capacitor 702/704, as is depicted. In another embodiment, one or more additional metal plate and intervening dielectric liner layer pairs are included over the metal plate 708 and intervening dielectric liner layer 706. In another embodiment, one or more metal plate and intervening dielectric liner layer pairs are included below a “finger” capacitor. In another embodiment, one or more metal plate and intervening dielectric liner layer pairs are included both above and below a “finger” capacitor.

With reference again to FIGS. 6 and 7, a state-of-the-art finger capacitor for integrated CMOS capacitors is shown in FIG. 6. A dielectric with constant dielectric constant is assumed, which was also used in the simulation described below. It is to be appreciated that the capacitor can be processed layers with different dielectrics. As shown in FIG. 7, in accordance with an embodiment of the present disclosure, a thin dielectric 706 (preferably with a relatively higher dielectric constant than the surrounding dielectric layer) and metallic plate are added to a finger structure. The dielectric and metal can be above, below or above and below the finger structure. In an embodiment, the metal plate is typically floating and leads to an increase of the capacitance density, since both polarity fingers couple with high capacitance to the plate.

In an embodiment, this configuration of a capacitor structure described in association with FIG. 7 can have several advantages. The capacitor density can be increased by the additional capacitor component. The added processing operations include only added thin layers and do not require high resolution lithography. The processing operations are therefore inexpensive, and also existing layers in the process might be used (e.g. barrier layers). The process control for the thickness of such layers can be very good and lower tolerance. The metal plate can reduce the series inductance of fingers (e.g., the inductance of a tracer over a ground plane, which decreases with the distance to plane). Since the metal can be patterned with course design rules, the thickness can be increased to reduce the sheet resistance. Also very thin layers could be chosen with good effectiveness on cap density and tolerance if low added height is a priority for the integration scheme. With the usage of less metal finger layers (exploiting the higher capacitor density), the free metal layers can be used for routing. Also, parasitic capacitance can be reduced.

In an embodiment, a dielectric layer of a capacitor includes a high-k material. For example, in one embodiment, the capacitor dielectrics are composed of a material such as, but not limited to, hafnium oxide, hafnium oxy-nitride, hafnium silicate, lanthanum oxide, zirconium oxide, zirconium silicate, tantalum oxide, barium strontium titanate, barium titanate, strontium titanate, yttrium oxide, aluminum oxide, lead scandium tantalum oxide, lead zinc niobate, or a combination thereof. In one embodiment, the corresponding electrodes are composed of a metal layer such as, but not limited to, metal nitrides (TiN or TaN), metal carbides, metal silicides, metal aluminides, hafnium, zirconium, titanium, tantalum, aluminum, ruthenium, palladium, platinum, cobalt, nickel or conductive metal oxides.

It is to be appreciated that the layers and materials described above in association with back-end-of-line (BEOL) structures and processing may be formed on or above an underlying semiconductor substrate or structure, such as underlying device layer(s) of an integrated circuit. In an embodiment, an underlying semiconductor substrate represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon and silicon on insulator (SOI), as well as similar substrates formed of other semiconductor materials, such as substrates including germanium, carbon, or group III-V materials. The semiconductor substrate, depending on the stage of manufacture, often includes transistors, integrated circuitry, and the like. In other embodiments, such features are not formed and a passive interposer is fabricated. The substrate may also include semiconductor materials, metals, dielectrics, dopants, and other materials commonly found in semiconductor substrates. Furthermore, the structures depicted may be fabricated on underlying lower level interconnect layers.

Although the preceding methods of fabricating a metallization layer, or portions of a metallization layer, of a BEOL metallization layer are described in detail with respect to select operations, it is to be appreciated that additional or intermediate operations for fabrication may include standard microelectronic fabrication processes such as lithography, etch, thin films deposition, planarization (such as chemical mechanical polishing (CMP)), diffusion, metrology, the use of sacrificial layers, the use of etch stop layers, the use of planarization stop layers, or any other associated action with microelectronic component fabrication. Also, it is to be appreciated that the process operations described for the preceding process flows may be practiced in alternative sequences, not every operation need be performed or additional process operations may be performed or both.

In an embodiment, as used throughout the present description, interlayer dielectric (ILD) material is composed of or includes a layer of a dielectric or insulating material. Examples of suitable dielectric materials include, but are not limited to, oxides of silicon (e.g., silicon dioxide (SiO₂)), doped oxides of silicon, fluorinated oxides of silicon, carbon doped oxides of silicon, various low-k dielectric materials known in the arts, and combinations thereof. The interlayer dielectric material may be formed by techniques, such as, for example, chemical vapor deposition (CVD), physical vapor deposition (PVD), or by other deposition methods.

In an embodiment, as is also used throughout the present description, metal lines or interconnect line material (and via material) is composed of one or more metal or other conductive structures. A common example is the use of copper lines and structures that may or may not include barrier layers between the copper and surrounding ILD material. As used herein, the term metal includes alloys, stacks, and other combinations of multiple metals. For example, the metal interconnect lines may include barrier layers (e.g., layers including one or more of Ta, TaN, Ti or TiN), stacks of different metals or alloys, etc. Thus, the interconnect lines may be a single material layer, or may be formed from several layers, including conductive liner layers and fill layers. Any suitable deposition process, such as electroplating, chemical vapor deposition or physical vapor deposition, may be used to form interconnect lines. In an embodiment, the interconnect lines are composed of a conductive material such as, but not limited to, Cu, Al, Ti, Zr, Hf, V, Ru, Co, Ni, Pd, Pt, W, Ag, Au or alloys thereof. The interconnect lines are also sometimes referred to in the art as traces, wires, lines, metal, or simply interconnect.

In an embodiment, as is also used throughout the present description, hardmask materials are composed of dielectric materials different from the interlayer dielectric material. In one embodiment, different hardmask materials may be used in different regions so as to provide different growth or etch selectivity to each other and to the underlying dielectric and metal layers. In some embodiments, a hardmask layer includes a layer of a nitride of silicon (e.g., silicon nitride) or a layer of an oxide of silicon, or both, or a combination thereof. Other suitable materials may include carbon-based materials. In another embodiment, a hardmask material includes a metal species. For example, a hardmask or other overlying material may include a layer of a nitride of titanium or another metal (e.g., titanium nitride). Potentially lesser amounts of other materials, such as oxygen, may be included in one or more of these layers. Alternatively, other hardmask layers known in the arts may be used depending upon the particular implementation. The hardmask layers maybe formed by CVD, PVD, or by other deposition methods.

In an embodiment, as is also used throughout the present description, lithographic operations are performed using 193 nm immersion lithography (i193), extreme ultra-violet (EUV) lithography or electron beam direct write (EBDW) lithography, or the like. A positive tone or a negative tone resist may be used. In one embodiment, a lithographic mask is a tri-layer mask composed of a topographic masking portion, an anti-reflective coating (ARC) layer, and a photoresist layer. In a particular such embodiment, the topographic masking portion is a carbon hardmask (CHM) layer and the anti-reflective coating layer is a silicon ARC layer.

Embodiments disclosed herein may be used to manufacture a wide variety of different types of integrated circuits or microelectronic devices. Examples of such integrated circuits include, but are not limited to, processors, chipset components, graphics processors, digital signal processors, micro-controllers, and the like. In other embodiments, semiconductor memory may be manufactured. Moreover, the integrated circuits or other microelectronic devices may be used in a wide variety of electronic devices known in the arts. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

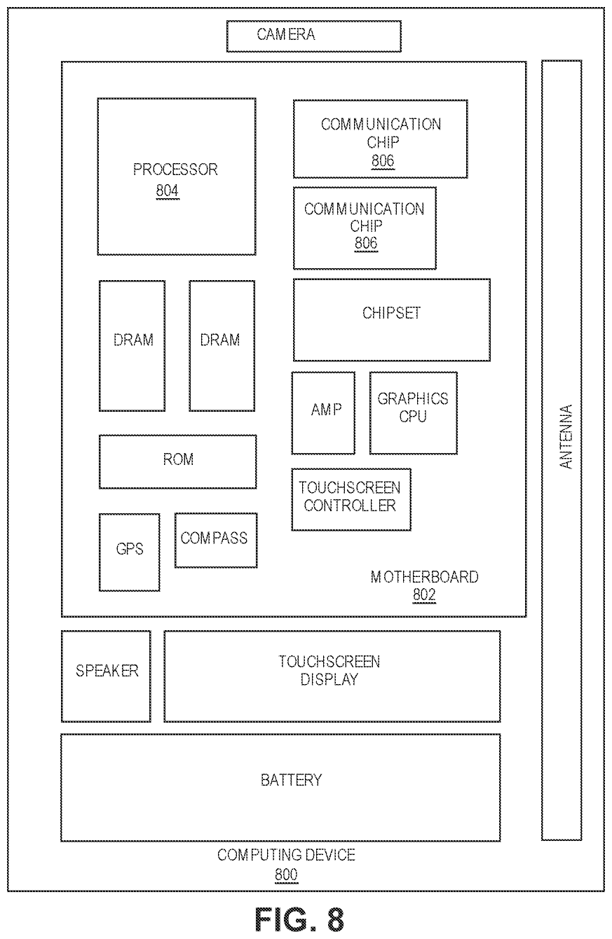

FIG. 8 illustrates a computing device 800 in accordance with one implementation of the disclosure. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804. In an embodiment, an interposer (such as a passive interposer including a protection device for a MIM capacitor) is included between the board 802 and one or more of the components.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. The term “processor” may refer to any device or portion of a device that processes electronic data from registers or memory to transform that electronic data, or both, into other electronic data that may be stored in registers or memory, or both. The communication chip 806 also includes an integrated circuit die packaged within the communication chip 806.

In various embodiments, the computing device 800 may be a laptop, a netbook, a notebook, an ultrabook, a smartphone, a tablet, a personal digital assistant (PDA), an ultramobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

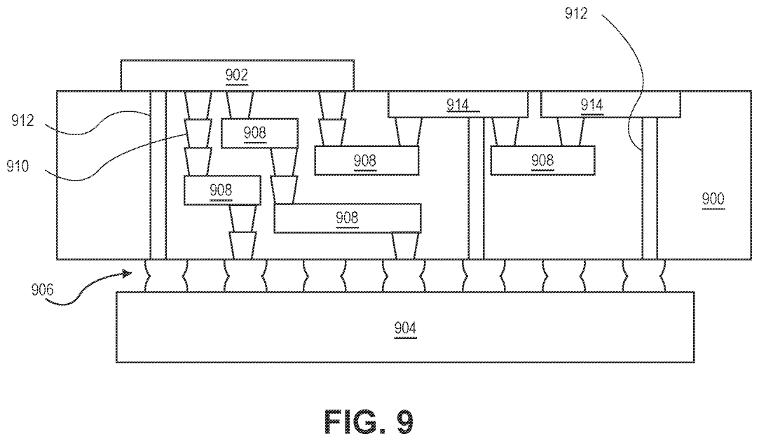

FIG. 9 illustrates an interposer 900 that includes one or more embodiments of the disclosure. The interposer 900 is an intervening substrate used to bridge a first substrate 902 to a second substrate 904. The first substrate 902 may be, for instance, an integrated circuit die. The second substrate 904 may be, for instance, a memory module, a computer motherboard, or another integrated circuit die. Generally, the purpose of an interposer 900 is to spread a connection to a wider pitch or to reroute a connection to a different connection. For example, an interposer 900 may couple an integrated circuit die to a ball grid array (BGA) 906 that can subsequently be coupled to the second substrate 904. In some embodiments, the first and second substrates 902/904 are attached to opposing sides of the interposer 900. In other embodiments, the first and second substrates 902/904 are attached to the same side of the interposer 900. And, in further embodiments, three or more substrates are interconnected by way of the interposer 900.

The interposer 900 may be formed of an epoxy resin, a fiberglass-reinforced epoxy resin, a ceramic material, or a polymer material such as polyimide. In further implementations, the interposer 900 may be formed of alternate rigid or flexible materials that may include the same materials described above for use in a semiconductor substrate, such as silicon, germanium, and other group III-V and group IV materials.

The interposer 900 may include metal interconnects 908 and vias 910, including but not limited to through-silicon vias (TSVs) 912. The interposer 900 may further include embedded devices 914, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 900. In accordance with embodiments of the disclosure, apparatuses or processes disclosed herein may be used in the fabrication of interposer 900 or in the fabrication of components included in the interposer 900.

Thus, embodiments of the present disclosure include protection devices for metal insulator metal (MIM) capacitors.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

The following examples pertain to further embodiments. The various features of the different embodiments may be variously combined with some features included and others excluded to suit a variety of different applications.

Example embodiment 1: An electronic assembly includes a semiconductor substrate. A dielectric layer is on the semiconductor substrate. A conductive via is in an opening in the dielectric layer, the conductive via in direct contact with the semiconductor substrate. A metal-insulator-metal (MIM) capacitor structure is electrically coupled to the conductive via.

Example embodiment 2: The electronic assembly of example embodiment 1, wherein the electronic assembly is a passive interposer.

Example embodiment 3: The electronic assembly of example embodiment 1 or 2, wherein the semiconductor substrate includes silicon.

Example embodiment 4: The electronic assembly of example embodiment 1, 2 or 3, wherein the conductive via includes copper.

Example embodiment 5: The electronic assembly of example embodiment 1, 2, 3 or 4, wherein the conductive via and the semiconductor substrate form a Schottky diode.

Example embodiment 6: The electronic assembly of example embodiment 1, 2, 3, 4 or 5, wherein the MIM capacitor structure is a topographical or trench MIM capacitor.

Example embodiment 7: The electronic assembly of example embodiment 1, 2, 3, 4 or 5, wherein the MIM capacitor structure is a stacked plate MIM capacitor.

Example embodiment 8: The electronic assembly of example embodiment 1, 2, 3, 4 or 5, wherein the MIM capacitor structure is a finger MIM capacitor.

Example embodiment 9: The electronic assembly of example embodiment 1, 2, 3, 4, 5, 6, 7 or 8, further including one or more routing layers between the conductive via and the MIM capacitor structure.

Example embodiment 10: The electronic assembly of example embodiment 1, 2, 3, 4, 5, 6, 7, 8 or 9, wherein the MIM capacitor structure is electrically coupled to the conductive via by a net of the MIM capacitor structure.

Example embodiment 11: The electronic assembly of example embodiment 1, 2, 3, 4, 5, 6, 7, 8, 9 or 10, wherein the conductive via includes a conductive liner and a conductive fill.

Example embodiment 12: The electronic assembly of example embodiment 11, wherein the conductive liner includes tantalum, and the conductive fill includes copper.

Example embodiment 13: A passive interposer includes a metal-insulator-metal (MIM) capacitor structure above a semiconductor substrate. A Schottky back-to-back diode is in direct contact with the semiconductor substrate, the Schottky back-to-back diode electrically coupled to the MIM capacitor structure. An antenna is coupled to the MIM capacitor structure. The Schottky back-to-back diode protects the MIM structure from the antenna.

Example embodiment 14: The passive interposer of example embodiment 13, wherein the semiconductor substrate includes silicon.

Example embodiment 15: The passive interposer of example embodiment 13 or 14, wherein the Schottky back-to-back diode includes one or more conductive vias in direct contact with the semiconductor substrate.

Example embodiment 16: A system includes a die. A passive interposer is coupled to the die. The passive interposer includes a semiconductor substrate, a dielectric layer on the semiconductor substrate, a conductive via in an opening in the dielectric layer, the conductive via in direct contact with the semiconductor substrate, and a metal-insulator-metal (MIM) capacitor structure electrically coupled to the conductive via.

Example embodiment 17: The system of example embodiment 16, wherein the MIM capacitor structure is a topographical or trench MIM capacitor.

Example embodiment 18: The system of example embodiment 16, wherein the MIM capacitor structure is a stacked plate MIM capacitor.

Example embodiment 19: The system of example embodiment 16, wherein the MIM capacitor structure is a finger MIM capacitor.

Example embodiment 20: The system of example embodiment 16, 17, 18 or 19, further including a board coupled to the passive interposer.

What is claimed is:

1. An electronic assembly, comprising:
a semiconductor substrate;
a dielectric layer on the semiconductor substrate;
a conductive via in an opening in the dielectric layer, the conductive via in direct contact with the semiconductor substrate; and
a metal-insulator-metal (MIM) capacitor structure electrically coupled to the conductive via.

2. The electronic assembly of claim 1, wherein the electronic assembly is a passive interposer.

3. The electronic assembly of claim 1, wherein the semiconductor substrate comprises silicon.

4. The electronic assembly of claim 1, wherein the conductive via comprises copper.

5. The electronic assembly of claim 1, wherein the conductive via and the semiconductor substrate form a Schottky diode.

6. The electronic assembly of claim 1, wherein the MIM capacitor structure is a topographical or trench MIM capacitor.

7. The electronic assembly of claim 1, wherein the MIM capacitor structure is a stacked plate MIM capacitor.

8. The electronic assembly of claim 1, wherein the MIM capacitor structure is a finger MIM capacitor.

9. The electronic assembly of claim 1, further comprising:
one or more routing layers between the conductive via and the MIM capacitor structure.

10. The electronic assembly of claim 1, wherein the MIM capacitor structure is electrically coupled to the conductive via by a net of the MIM capacitor structure.

11. The electronic assembly of claim 1, wherein the conductive via includes a conductive liner and a conductive fill.

12. The electronic assembly of claim 11, wherein the conductive liner comprises tantalum, and the conductive fill comprises copper.

13. A passive interposer, comprising:
a metal-insulator-metal (MIM) capacitor structure above a semiconductor substrate;
a Schottky back-to-back diode in direct contact with the semiconductor substrate, the Schottky back-to-back diode electrically coupled to the MIM capacitor structure; and
an antenna coupled to the MIM capacitor structure, wherein the Schottky back-to-back diode protects the MIM structure from the antenna.

14. The passive interposer of claim 13, wherein the semiconductor substrate comprises silicon.

15. The passive interposer of claim 13, wherein the Schottky back-to-back diode comprises one or more conductive vias in direct contact with the semiconductor substrate.

16. A system, comprising:
a die; and
a passive interposer coupled to the die, the passive interposer comprising a semiconductor substrate, a dielectric layer on the semiconductor substrate, a conductive via in an opening in the dielectric layer, the conductive via in direct contact with the semiconductor substrate, and a metal-insulator-metal (MIM) capacitor structure electrically coupled to the conductive via.

17. The system of claim 16, wherein the MIM capacitor structure is a topographical or trench MIM capacitor.

18. The system of claim 16, wherein the MIM capacitor structure is a stacked plate MIM capacitor.

19. The system of claim 16, wherein the MIM capacitor structure is a finger MIM capacitor.

20. The system of claim 16, further comprising:
a board coupled to the passive interposer.
